(19) United States
(12) Patent Application Publication
(10) Pub. No.: US 2026/0319386 A1
(43) Pub. Date: Oct. 15, 2026

(54) SUBSTRATE SUPPORT MEMBER, SUBSTRATE STAGE MECHANISM, LITHOGRAPHY APPARATUS, AND ARTICLE MANUFACTURING METHOD

(71) Applicant: CANON KABUSHIKI KAISHA, Tokyo (JP)

(72) Inventors: TAKATO YUASA, Tochigi (JP); KAZUNORI NAKAJIMA, Tokyo (JP); SHIGEO KOYA, Tochigi (JP)

(21) Appl. No.: 19/646,407

(22) Filed: Apr. 13, 2026

(30) Foreign Application Priority Data
Apr. 15, 2025 (JP) 2025-067034

(51) Int. Cl. G03F 7/00; H10P 72/76

(52) U.S. Cl. CPC G03F 7/70716; H10P 72/7614

(57) ABSTRACT

A substrate support member that supports a substrate includes a base; a plurality of first pins arranged on the base; a protrusion arranged on the base so as to surround a region where the plurality of first pins are arranged; a plurality of second pins arranged on an upper surface of the protrusion; and a plurality of third pins arranged on the base between the protrusion and an outer edge of the base, wherein the plurality of first pins, the plurality of second pins, and the plurality of third pins support the substrate.

### BACKGROUND

### Field of the Technology

The present disclosure relates to a substrate support member, a substrate stage mechanism, a lithography apparatus, and an article manufacturing method.

### Description of the Related Art

Japanese Patent Laid-Open No. 2007-273693 describes a substrate holding member that holds a substrate. The substrate holding member includes a holding member main body, a first annular protrusion formed on the upper surface of the holding member main body, at least one second annular protrusion formed inside the first annular protrusion, and a plurality of pin-shaped support portions arranged in a region inside the first annular protrusion. At least one exhaust port is formed in the region inside the innermost second annular protrusion. The plurality of pin-shaped support portions support a substrate so that a clearance is formed between the second annular protrusion and the substrate. When the substrate is placed on the holding member main body, a nearly closed space is formed by the first annular protrusion, the substrate, and the upper surface of the holding member main body. This space is partitioned into a plurality of spaces (the number larger than the number of the second annular protrusions by one) by the at least one second annular protrusion. The plurality of spaces communicate with each other via a clearance between the back surface of the substrate and the distal end of each second annular protrusion. Therefore, in this state, when the gas in the space formed by the first annular protrusion, the substrate, and the upper surface of the holding member main body is exhausted via the exhaust port, the pressure in the central space in direct communication with the exhaust port starts to decrease, and subsequently, the pressure in the outer adjacent space gradually decreases. That is, the substrate is supported by the substrate holding member from the central portion toward the outer periphery of the substrate with a time lag. According to Japanese Patent Laid-Open No. 2007-273693, it is possible to hold even a substrate with warpage while keeping the flatness of the substrate at nearly the same high level over almost the entire region.

In a case of providing the second annular protrusion as described in Japanese Patent Laid-Open No. 2007-273693, the flatness of the substrate can decrease since a portion of the substrate above the second annular protrusion is not supported.

### SUMMARY

The present disclosure provides a technique advantageous for supporting a substrate with high flatness.

The present disclosure provides a substrate support member that supports a substrate, comprising: a base; a plurality of first pins arranged on the base; a protrusion arranged on the base so as to surround a region where the plurality of first pins are arranged; a plurality of second pins arranged on an upper surface of the protrusion; and a plurality of third pins arranged on the base between the protrusion and an outer edge of the base, wherein the plurality of first pins, the plurality of second pins, and the plurality of third pins support the substrate.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing the configuration of a lithography apparatus according to an embodiment;

FIG. 2 is a plan view schematically showing the configuration of a substrate support member according to an embodiment;

FIG. 3 is a plan view schematically showing the configuration of the substrate support member according to the embodiment;

FIG. 4 is a sectional view showing a section of the substrate support member shown in FIG. 2 taken along a straight line passing through the center of the substrate support member;

FIG. 5 is a sectional view showing a section of the substrate support member shown in FIG. 2 taken along a straight line passing through the center of the substrate support member;

FIG. 6 is a plan view schematically showing the configuration of a substrate support member according to another embodiment; and

FIG. 7 is a plan view schematically showing the configuration of a substrate support member according to still another embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

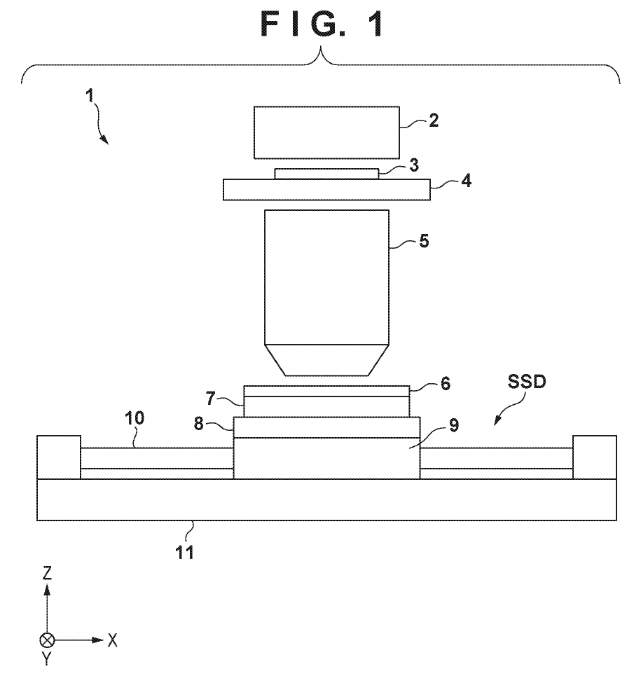

FIG. 1 is a schematic view showing the configuration of a lithography apparatus 1 according to an embodiment. The lithography apparatus 1 is an apparatus that forms a pattern on a substrate 6. The lithography apparatus 1 can be configured as, for example, an exposure apparatus that projects the pattern of an original 3 onto the substrate 6 to form a latent image pattern in a photosensitive material applied on the substrate 6. Alternatively, the lithography apparatus 1 can be configured as, for example, an imprint apparatus that transfers the pattern of a mold serving as an original to a curable composition applied on the substrate 6.

FIG. 1 shows an example in which the lithography apparatus 1 is configured as an exposure apparatus. The lithography apparatus 1 can include an illumination optical system 2 that illuminates the original 3, an original stage mechanism 4 that positions the original 3, a projection optical system 5 that projects the pattern of the original 3 onto the substrate 6, and a substrate stage mechanism SSD that positions the substrate 6. The substrate stage mechanism SSD can include a mover 9, a driving mechanism 10 that drives the mover 9, and a substrate support member 7 that is mounted on the mover 9 and supports the substrate 6. The substrate stage mechanism SSD may include a top plate 8 mounted on the mover 9. In this case, the substrate support member 7 can be mounted on the top plate 8.

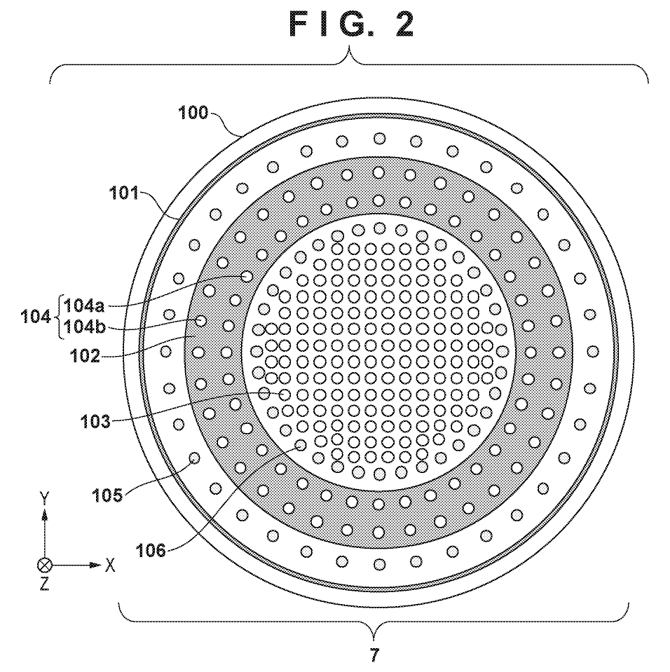

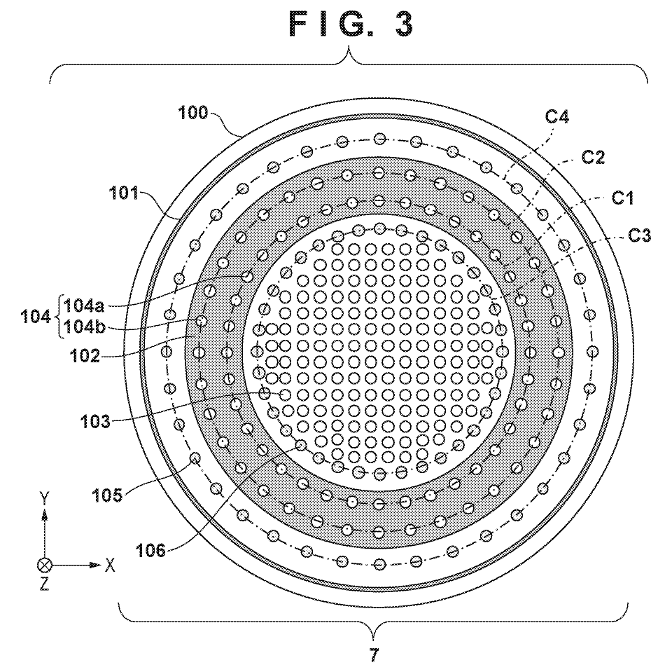

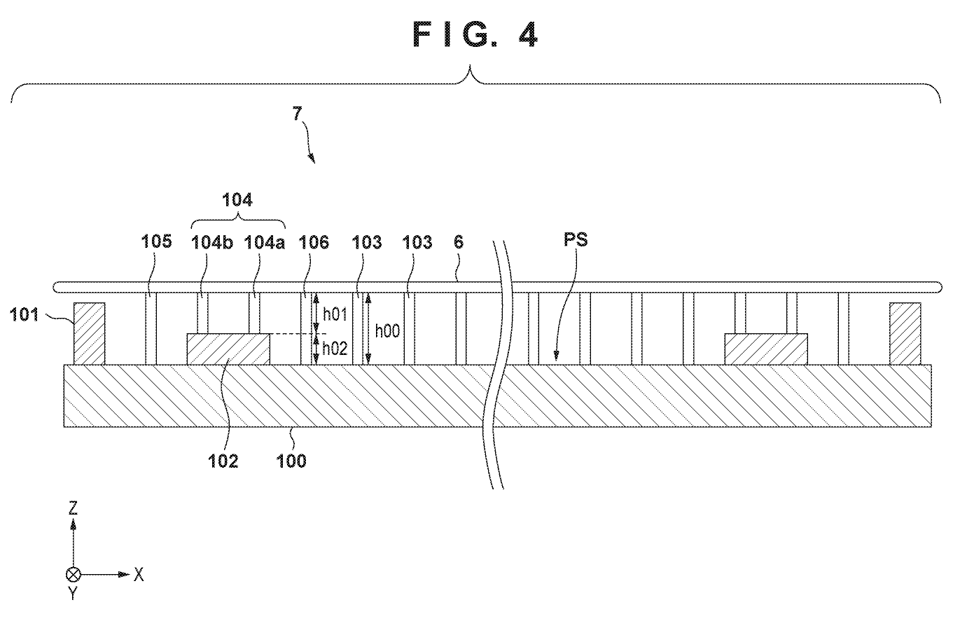

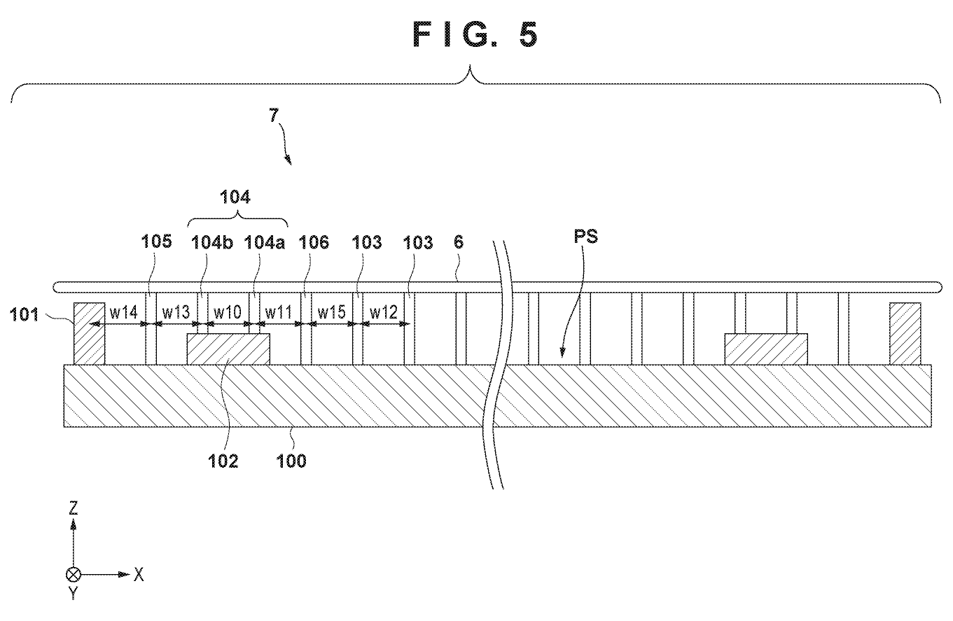

FIG. 2 is a plan view schematically showing the configuration of the substrate support member 7 according to an embodiment. FIG. 3 is a plan view obtained by adding virtual circles C1, C2, C3, and C4 to FIG. 2 for the sake of descriptive convenience. FIGS. 4 and 5 are sectional views each showing a section of the substrate support member 7 shown in FIG. 2 taken along a straight line passing through the center of the substrate support member 7.

The substrate support member 7 can be made of a material having excellent thermal conductivity, for example, SiC ceramics. The substrate support member 7 can include a base 100, a plurality of first pins 103 arranged on the base 100, a protrusion 102 arranged on the base 100 so as to surround a region where the plurality of first pins 103 are arranged, and a plurality of second pins 104 arranged on the upper surface of the protrusion 102. The base 100 includes a main surface PS. The plurality of first pins 103 can be arranged on the main surface PS of the base 100, and the protrusion 102 can be arranged on the main surface PS of the base 100. The substrate 6 can be supported by the plurality of first pins 103 and the plurality of second pins 104. From another viewpoint, the substrate 6 can be supported by the distal ends of the plurality of first pins 103 and the distal ends of the plurality of second pins 104. The distal ends of the plurality of first pins 103 and the distal ends of the plurality of second pins 104 can be arranged to belong to one virtual plane. The substrate 6 can be supported by the substrate support member 7 so that its lower surface matches the virtual plane. The base 100 can have a disc shape.

Although not shown, the base 100 is provided with one or a plurality of exhaust ports which are used to exhaust the gas in a space between the main surface PS and the substrate 6 to decrease the pressure in the space. The one or plurality of exhaust ports are arranged in a region surrounded by the protrusion 102. The base 100 can be provided with opening portions for storing support members (for example, support pins) which are used when loading the substrate 6 onto the substrate support member 7 and unloading the substrate 6 from the substrate support member 7.

The protrusion 102 can have an annular shape. The protrusion 102 may be divided into a plurality of arc-shaped portions each having an arc shape. In this case, a gap can be provided between the adjacent arc-shaped portions. At least two second pins 104 can be provided on the upper surface of each arc-shaped portion. The plurality of second pins 104 can include second pins 104a of the first group arranged on the circumference of the first circle C1 which is concentric with the annular shape of the protrusion 102. The plurality of second pins 104 can also include second pins 104b of the second group arranged on the circumference of the second circle C2 which is concentric with the first circle C1 and has a larger radius than the first circle C1. Although not shown, the plurality of second pins 104 may include the second pins of the third group arranged on the circumference of one circle or circumferences of two or more circles, each circle being concentric with the second circle C2 and having a larger radius than the second circle C2.

Each of the second pins 104a of the first group can be arranged on a straight line connecting the second pin 104b of the second group and the center of the annular shape of the protrusion 102. Alternatively, each of the second pins 104a of the first group may be arranged at a position shifted from the straight line connecting the second pin 104b of the second group and the center of the annular shape of the protrusion 102 in a circumferential direction.

The substrate support member 7 may further include a plurality of fourth pins 106 arranged on the main surface PS of the base 100 between the protrusion 102 and the region where the plurality of first pins 103 are arranged. The plurality of fourth pins 106 can be arranged on the circumference of the third circle C3 which is concentric with the annular shape of the protrusion 102. The distal ends of the plurality of fourth pins 106 can support the substrate 6 together with the distal ends of the plurality of first pins 103 and the distal ends of the plurality of second pins 104. The distal ends of the plurality of first pins 103, the distal ends of the plurality of second pins 104, and the distal ends of the plurality of fourth pins 106 can be arranged to belong to one virtual plane. The substrate 6 can be supported by the substrate support member 7 so that its lower surface matches the virtual plane.

The substrate support member 7 can further include a plurality of third pins 105 arranged on the main surface PS of the base 100 between the protrusion 102 and the outer edge of the base 100. The plurality of third pins 105 can be arranged on the circumference of the fourth circle C4 which is concentric with the annular shape of the protrusion 102. The distal ends of the plurality of third pins 105 can support the substrate 6 together with the distal ends of the plurality of first pins 103 and the distal ends of the plurality of second pins 104. The distal ends of the plurality of first pins 103, the distal ends of the plurality of second pins 104, and the distal ends of the plurality of third pins 105 can be arranged to belong to one virtual plane. The substrate 6 can be supported by the substrate support member 7 so that its lower surface matches the virtual plane. From another viewpoint, the distal ends of the plurality of first pins 103, the distal ends of the plurality of second pins 104, the distal ends of the plurality of fourth pins 106, and the distal ends of the plurality of third pins 105 can be arranged to belong to one virtual plane. The substrate 6 can be supported by the substrate support member 7 so that its lower surface matches the virtual plane.

In an example, a height dimension h02 of the protrusion 102 is smaller than a height dimension h01 of the second pin 104. In another example, the height dimension h02 of the protrusion 102 is larger than the height dimension h01 of the second pin 104. When the main surface PS is a flat surface, a height dimension h00 of the first pin 103 is equal to the sum of the height dimension h02 of the protrusion 102 and the height dimension h01 of the second pin 104.

As schematically shown in FIG. 2, the plurality of second pins 104, the plurality of fourth pins 106, and the plurality of third pins 105 can be arranged radially. In other words, one second pin 104, one fourth pin 106, and one third pin 105 can be arranged on the radius of the annular shape of the protrusion 102 or the radius of the base 100. From another viewpoint, one second pin 104 and one fourth pin 106 can be arranged on a radius connecting one third pin 105 and the center of the annular shape of the protrusion 102 or the center of the base 100.

The substrate support member 7 can further include an outer protrusion 101 arranged on the main surface PS of the base 100 so as to surround the plurality of third pins 105. The height of the upper surface of the outer protrusion 101 may be lower than the height of each of the distal ends of the plurality of first pins 103 and the distal ends of the plurality of second pins 104. Alternatively, the height of the upper surface of the outer protrusion 101 may be lower than the height of each of the distal ends of the plurality of first pins 103, the distal ends of the plurality of second pins 104, the distal ends of the plurality of fourth pins 106, and the distal ends of the plurality of third pins 105. In a state in which the substrate 6 is supported by the substrate support member 7, a gap is formed between the upper surface of the outer protrusion 101 and the lower surface of the substrate 6. Unlike the above, the height of the upper surface of the outer protrusion 101 may be equal to the height of each of the distal ends of the plurality of first pins 103 and the distal ends of the plurality of second pins 104.

A radius difference w10 between the first circle C1 on which the second pins 104a of the first group are arranged and the second circle C2 on which the second pins 104b of the second group are arranged may be 1 mm or more and 3 mm or less, and is preferably 1.7 mm or more and 2.2 mm or less.

A radius difference w11 between the first circle C1 on which the second pins 104a of the first group are arranged and the fourth circle C4 on which the plurality of fourth pins 106 are arranged may be 1 mm or more and 3 mm or less, and is preferably 1.7 mm or more and 2.2 mm or less.

The arrangement pitch w12 of the plurality of first pins 103 in the radius direction of the annular shape of the protrusion 102 may be 1 mm or more and 3 mm or less, and is preferably 1.7 mm or more and 2.2 mm or less.

A radius difference w13 between the second circle C2 on which the second pins 104b of the second group are arranged and the third circle C3 on which the plurality of third pins 105 are arranged may be 1 mm or more and 3 mm or less, and is preferably 1.7 mm or more and 2.2 mm or less.

A minimum distance w15 between the fourth circle C4 on which the plurality of fourth pins 106 are arranged and the center of each of the plurality of first pins 103 may be 1 mm or more and 3 mm or less, and is preferably 1.7 mm or more and 2.2 mm or less.

A distance w14 between the plurality of third pins 105 and the radial center of the outer protrusion 101 may be 1 mm or more and 3 mm or less, and is preferably 1.7 mm or more and 2.2 mm or less.

In an example, w10 = W11, or w10 = W13, or w10 = w11 = w13, or w10 = w11 = w13 = w12, or w10 = w11 = w13 = w12 = w15, or w10 = w11 = w13 = w12 = w15 = w14 can be satisfied.

The radial width of the annular shape of the protrusion 102 is larger than the minimum distance in a plurality of pins including the plurality of first pins 103, the plurality of second pins 104, and the plurality of third pins 105.

The configuration including the protrusion 102 whose height is lower than the distal ends of the plurality of first pins 103 is advantageous for first decompressing the space inside the protrusion 102 and then decompressing the space outside the protrusion 102. With this configuration, the central portion of the substrate 6 is first attracted to the substrate support member 7 (strictly speaking, it is pressed against the substrate support member 7 by atmospheric pressure), and then the peripheral portion of the substrate 6 is attracted to the substrate support member 7. Thus, the substrate support member 7 can easily hold even the substrate 6 with warpage.

The configuration with the plurality of second pins 104 arranged on the upper surface of the protrusion 102 is advantageous for supporting the substrate 6 with high flatness. This is because, even above the protrusion 102, the substrate 6 is supported by the second pins 104.

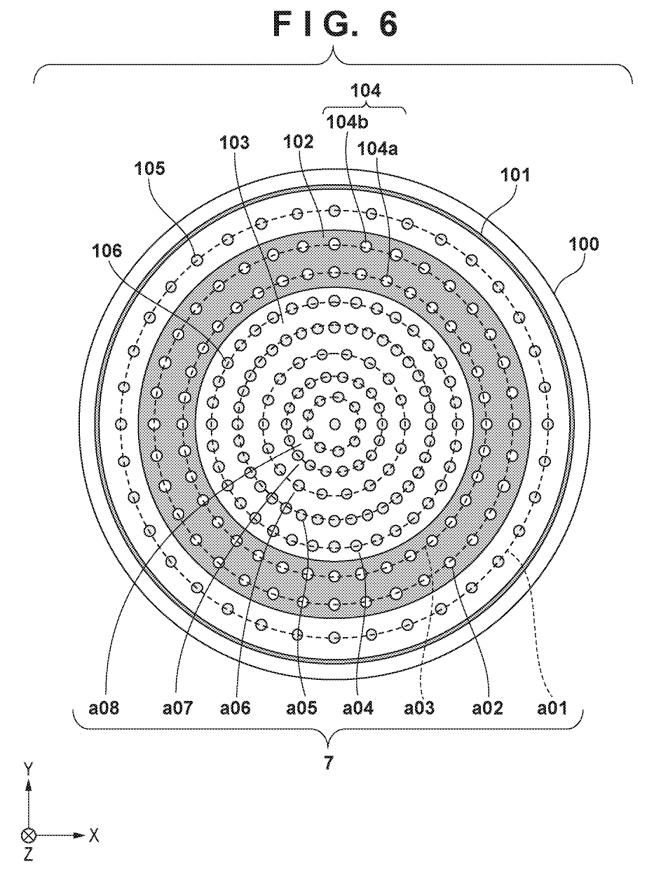

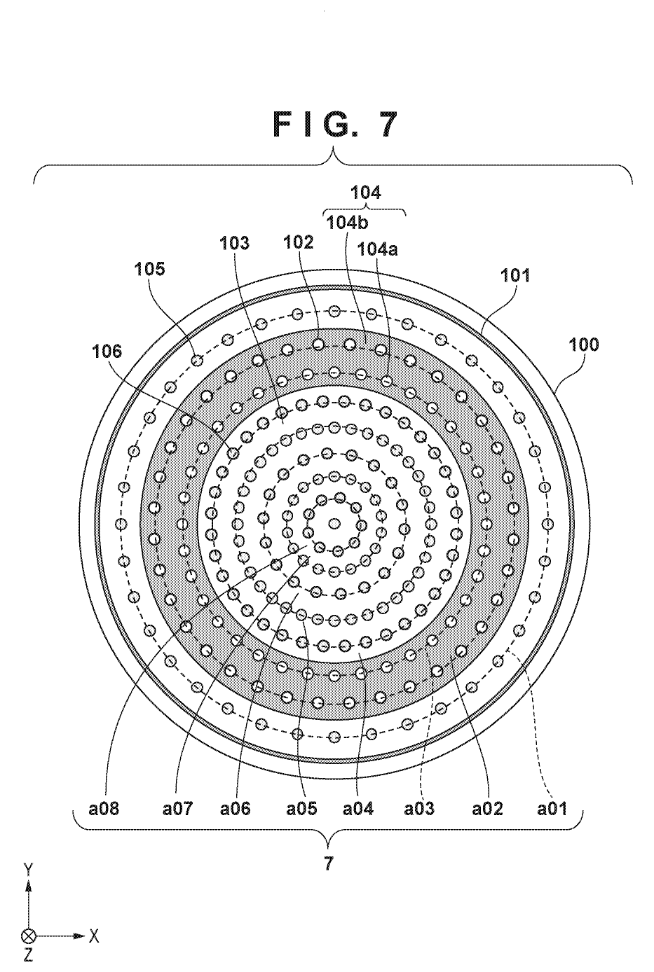

In the substrate support member 7 shown in FIGS. 2 and 3, the plurality of first pins 103 are arranged in a matrix pattern. However, this is merely an example. As schematically shown in FIG. 6 or 7, the plurality of first pins 103 may be arranged radially, may be arranged concentrically, or may be arranged radially and concentrically.

The plurality of first pins 103, the plurality of second pins 104, the plurality of fourth pins 106, and the plurality of third pins 105 may all have the same diameter, or may respectively have adjusted diameters.

Here, in the example schematically shown in each of FIGS. 6 and 7, the plurality of pins including the plurality of first pins 103, the plurality of second pins 104, the plurality of fourth pins 106, and the plurality of third pins 105 are arranged to form the arrangement of a plurality of concentric circles a01 to a08. In the example schematically shown in FIG. 6, the pins are arranged so that the pins on all the concentric circles align in the radial direction. From another viewpoint, in the example schematically shown in FIG. 6, the pins are arranged so that the pins on the adjacent concentric circles align in the radial direction. Letting n be the number of pins on each concentric circle, n pins are arranged at an angular interval of (360/n)° on all the concentric circles.

On the other hand, in the example schematically shown in FIG. 7, the pins are arranged so that the pins on all the odd-numbered concentric circles from the center align in the radial direction, and the pins on all the even-numbered concentric circles from the center align in the radial direction. From another viewpoint, in the example schematically shown in FIG. 7, the pins on the adjacent concentric circles are arranged not to align in the radial direction. Letting n be the number of pins on each concentric circle, n pins are arranged at an angular interval of (360/n)° on all the concentric circles. The minimum angular difference between the pin on the odd-numbered concentric circle and the pin on the even-numbered concentric circle can be (180/n)°.

The lithography apparatus 1 is applied to an article manufacturing method of manufacturing an article. The article manufacturing method can include a formation step of forming a pattern on a substrate by the lithography apparatus 1, and a processing step of obtaining an article by processing the substrate having undergone the formation step. The pattern formed in the formation step is, for example, a latent image formed in a photosensitive material on the substrate. The processing step can include, for example, a developing step. The processing step can additionally include a film formation step, an etching step, a dicing step, a sealing step, or the like. The article manufacturing method can execute the formation step of forming a pattern on a substrate, and processing (for example, the developing step) accompanying the formation step a plurality of times.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-067034, filed April 15, 2025, which is hereby incorporated by reference herein in its entirety.

What is claimed is:

1. A substrate support member that supports a substrate, comprising:
a base;
a plurality of first pins arranged on the base;
a protrusion arranged on the base so as to surround a region where the plurality of first pins are arranged;
a plurality of second pins arranged on an upper surface of the protrusion; and
a plurality of third pins arranged on the base between the protrusion and an outer edge of the base,
wherein the plurality of first pins, the plurality of second pins, and the plurality of third pins support the substrate.

2. The member according to claim 1, wherein
the protrusion has an annular shape.

3. The member according to claim 2, wherein
the plurality of second pins include second pins of a first group arranged on a circumference of a first circle which is concentric with the annular shape.

4. The member according to claim 3, wherein
the plurality of second pins include second pins of a second group arranged on a circumference of a second circle that is concentric with the first circle and has a radius larger than the first circle.

5. The member according to claim 2, further comprising a plurality of fourth pins arranged on the base between the protrusion and the region,
wherein
the plurality of fourth pins is arranged on a circumference of a fourth circle that is concentric with the annular shape, and
the plurality of fourth pins supports the substrate together with the plurality of first pins and the plurality of second pins.

6. The member according to claim 4, wherein
each of the second pins of the first group is arranged on a straight line connecting one of the second pins of the second group and a center of the annular shape.

7. The member according to claim 6, further comprising a plurality of fourth pins arranged on the base between the protrusion and the region,
wherein
the plurality of fourth pins is arranged on a circumference of a fourth circle that is concentric with the annular shape,
each of the plurality of fourth pins is arranged on a straight line connecting one of the second pins of the second group and a center of the annular shape, and
the plurality of fourth pins supports the substrate together with the plurality of first pins and the plurality of second pins.

8. The member according to claim 2, wherein
a radial width of the annular shape is larger than a minimum distance in a plurality of pins including the plurality of first pins, the plurality of second pins, and the plurality of third pins.

9. The member according to claim 1, wherein
a height dimension of the protrusion is smaller than a height dimension of the second pin.

10. The member according to claim 2, further comprising a plurality of fourth pins arranged on the base between the protrusion and the region,
wherein the plurality of second pins, the plurality of third pins, and the plurality of fourth pins are arranged radially.

11. The member according to claim 10, wherein
the plurality of first pins, the plurality of second pins, the plurality of third pins, and the plurality of fourth pins are arranged concentrically.

12. The member according to claim 10, further comprising an outer protrusion arranged on the base so as to surround the plurality of third pins.

13. The member according to claim 12, wherein
a height of an upper surface of the outer protrusion is lower than a height of each of the plurality of first pins and the plurality of second pins.

14. The member according to claim 7, wherein
a radius difference between the first circle and the second circle is not less than 1 mm and not more than 3 mm, and
a radius difference between the first circle and the fourth circle is not less than 1 mm and not more than 3 mm.

15. The member according to claim 14, wherein
an arrangement pitch of the plurality of first pins in a radius direction of the annular shape is not less than 1 mm and not more than 3 mm.

16. The member according to claim 6,
wherein
the plurality of third pins is arranged on a circumference of a third circle that is concentric with the annular shape, and
distal ends of the plurality of third pins support the substrate together with distal ends of the plurality of first pins and distal ends of the plurality of second pins.

17. The member according to claim 16, wherein
a radius difference between the first circle and the second circle is not less than 1 mm and not more than 3 mm, and
a radius difference between the second circle and the third circle is not less than 1 mm and not more than 3 mm.

18. A substrate stage mechanism comprising:
a mover;
a driving mechanism configured to drive the mover; and
a substrate support member mounted on the mover to support a substrate,
wherein the substrate support member comprises:
a base;
a plurality of first pins arranged on the base;
a protrusion arranged on the base so as to surround a region where the plurality of first pins are arranged;
a plurality of second pins arranged on an upper surface of the protrusion; and
a plurality of third pins arranged on the base between the protrusion and an outer edge of the base,
wherein the plurality of first pins, the plurality of second pins, and the plurality of third pins support the substrate.

19. A lithography apparatus comprising the substrate stage mechanism according to claim 18, and configured to form a pattern on a substrate supported by the substrate support member of the substrate stage mechanism.

20. An article manufacturing method comprising:
forming a pattern on a substrate by a lithography apparatus; and
obtaining an article by processing the substrate having undergone the forming,
wherein the lithography apparatus comprises a substrate stage mechanism, and configured to form a pattern on a substrate supported by the substrate support member of the substrate stage mechanism, and
wherein the substrate support member comprises:
a base;
a plurality of first pins arranged on the base;
a protrusion arranged on the base so as to surround a region where the plurality of first pins are arranged;
a plurality of second pins arranged on an upper surface of the protrusion; and
a plurality of third pins arranged on the base between the protrusion and an outer edge of the base,
wherein the plurality of first pins, the plurality of second pins, and the plurality of third pins support the substrate.
